(19) United States
(12) Patent Application Publication
(10) Pub. No.: US 2026/0123253 A1
(43) Pub. Date: Apr. 30, 2026

(54) DISPLAY PANEL, DISPLAY DEVICE, AND CARRIER

(71) Applicant: Shanghai Tianma Microelectronics Co., Ltd., Shanghai (CN)

(72) Inventors: Yaodong Wu, Shanghai (CN); Qijun Yao, Shanghai (CN)

(73) Assignee: Shanghai Tianma Microelectronics Co., Ltd., Shanghai (CN)

(21) Appl. No.: 19/433,425

(22) Filed: Dec. 26, 2025

(30) Foreign Application Priority Data
Sep. 17, 2025 (CN) 202511334660.8

(51) Int. Cl. H10K 59/80; G02B 5/04; H10H 29/855; H10H 29/856

(52) U.S. Cl. CPC H10K 59/879; G02B 5/045; H10H 29/855; H10H 29/856; H10K 59/878

(57) ABSTRACT

Provided are a display panel, a display device, and a carrier. The display panel includes a substrate, multiple pixel rows, and a prism array. The pixel rows are located on a side of the substrate, extend in a first direction, and are arranged in a second direction. A pixel row includes multiple sub-pixels arranged in the first direction. The first direction intersects the second direction. The prism array is located on a side of a layer where the pixel rows are located facing away from the substrate. The prism array includes multiple aspheric cylindrical prisms extending in the first direction and arranged in the second direction. The orthographic projection of at least one pixel row on the substrate overlaps the orthographic projection of an aspheric cylindrical prism on the substrate.

### CROSS-REFERENCE TO RELATED APPLICATION

This application claims priority to Chinese patent application No. 202511334660.8 filed with the China National Intellectual Property Administration (CNIPA) on Sep. 17, 2025, the disclosure of which is incorporated herein by reference in its entirety.

### TECHNICAL FIELD

The present disclosure relates to the field of display technology and, in particular, to a display panel, a display device, and a carrier.

### BACKGROUND

With the development of science and technology and the advancement of society, people are increasingly dependent on the exchange and transmission of information. As a main carrier and material basis of information exchange and transmission, a display has become a hot spot for many scientists.

In the panoramic head-up display (PHUD) technology, a screen is incident on the front windscreen of an automobile at approximately a Brewster angle, and light in other directions will not enter the human eye. Therefore, in the PHUD, the feature of high collimation is presented in the direction of a pitch angle, and a relatively great width exists at an azimuth angle. Regarding the preceding functions, when a light emission angle of the screen is designed, relatively high collimation is required for the pitch angle, and a relatively large light emission angle is required for the azimuth angle.

The light emission angle of the screen is usually an omnidirectional angle. However, the angle range of a user viewing the screen is limited, resulting in relatively low energy efficiency of the screen.

### SUMMARY

The present disclosure provides a display panel, a display device, and a carrier to improve the collimation of the emitted light, thereby adapting to the angle range of a user viewing a screen, improving the light energy utilization rate of the screen, and improving the energy efficiency of the screen.

An embodiment of the present disclosure provides a display panel. The display panel includes a substrate, multiple pixel rows, and a prism array.

The multiple pixel rows are located on a side of the substrate, extend in a first direction, and are arranged in a second direction. A pixel row includes multiple sub-pixels arranged in the first direction. The first direction intersects the second direction.

The prism array is located on a side of a layer where the multiple pixel rows are located facing away from the substrate. The prism array includes multiple aspheric cylindrical prisms extending in the first direction and arranged in the second direction.

An orthographic projection of at least one of the multiple pixel rows on the substrate overlaps an orthographic projection of an aspheric cylindrical prism of the multiple aspheric cylindrical prisms on the substrate.

An embodiment of the present disclosure provides a display device including the display panel described in the preceding embodiment.

An embodiment of the present disclosure provides a carrier including the display device described in the preceding embodiments and a windscreen.

### BRIEF DESCRIPTION OF DRAWINGS

FIG. 1 is a perspective view of a display panel according to an embodiment of the present disclosure.

FIG. 2 is a top view of a display panel according to an embodiment of the present disclosure.

FIG. 3 is a cross-sectional view taken along direction AA′ of FIG. 2.

FIG. 4 is another top view of a display panel according to an embodiment of the present disclosure.

FIG. 5 is a cross-sectional view taken along direction BB′ of FIG. 4.

FIG. 6 is another cross-sectional view of a display panel according to an embodiment of the present disclosure.

FIG. 7 is another cross-sectional view of a display panel according to an embodiment of the present disclosure.

FIG. 8 is another cross-sectional view of a display panel according to an embodiment of the present disclosure.

FIG. 9 is another cross-sectional view of a display panel according to an embodiment of the present disclosure.

FIG. 10 is another cross-sectional view of a display panel according to an embodiment of the present disclosure.

FIG. 11 is another cross-sectional view of a display panel according to an embodiment of the present disclosure.

FIG. 12 is another top view of a display panel according to an embodiment of the present disclosure.

FIG. 13 is a cross-sectional view taken along direction CC′ of FIG. 12.

FIG. 14 is another top view of a display panel according to an embodiment of the present disclosure.

FIG. 15 is a cross-sectional view taken along direction DD′ of FIG. 14.

FIG. 16 is another top view of a display panel according to an embodiment of the present disclosure.

FIG. 17 is a cross-sectional view taken along direction EE′ of FIG. 16.

FIG. 18 is another cross-sectional view of a display panel according to an embodiment of the present disclosure.

FIG. 19 is another cross-sectional view of a display panel according to an embodiment of the present disclosure.

FIG. 20 is another cross-sectional view of a display panel according to an embodiment of the present disclosure.

FIG. 21 is another cross-sectional view of a display panel according to an embodiment of the present disclosure.

FIG. 22 is another cross-sectional view of a display panel according to an embodiment of the present disclosure.

FIG. 23 is a view of a display device according to an embodiment of the present disclosure.

FIG. 24 is a diagram of a carrier according to an embodiment of the present disclosure.

FIG. 25 is another diagram of a carrier according to an embodiment of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

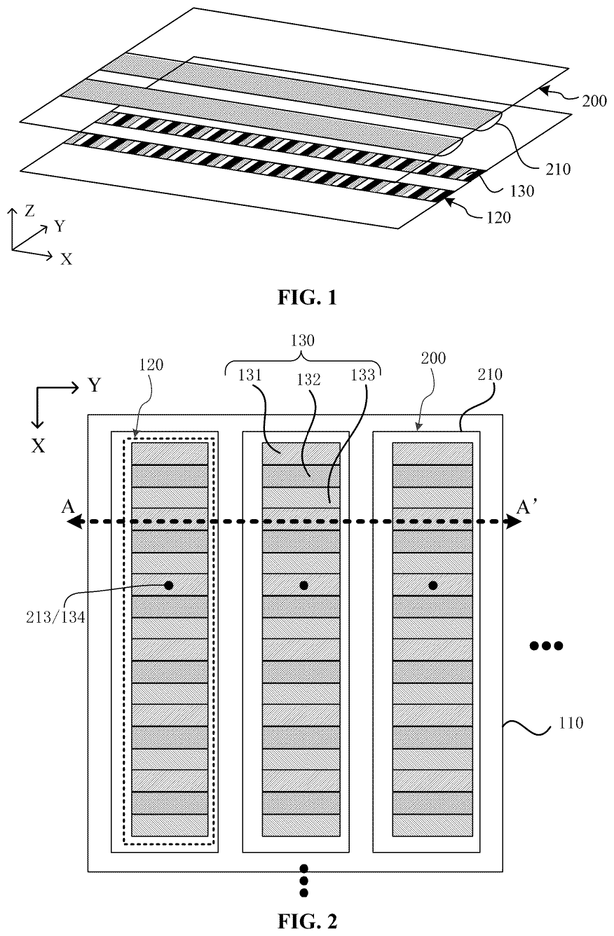

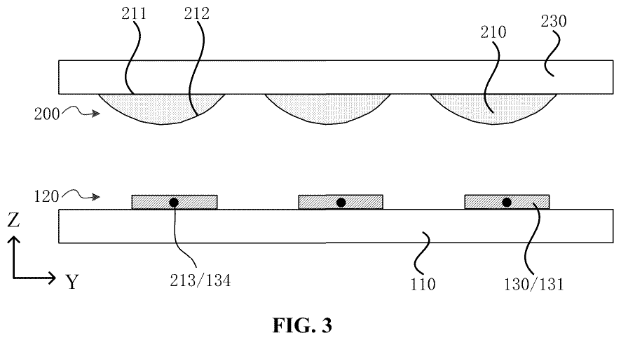

FIG. 1 is a perspective view of a display panel according to an embodiment of the present disclosure. FIG. 2 is a top view of a display panel according to an embodiment of the present disclosure. FIG. 3 is a cross-sectional view taken along direction AA′ of FIG. 2. Referring to FIGS. 1 to 3, the display panel includes a substrate 110, multiple pixel rows 120, and a prism array 200. The pixel rows 120 are located on a side of the substrate 110, extend in a first direction X, and are arranged in a second direction Y. A pixel row 20 includes multiple sub-pixels 130 arranged in the first direction X. The first direction X intersects the second direction Y. The first direction X and the second direction Y may be perpendicular to each other. Alternatively, an angle greater than 0° and less than 90° exists between the first direction X and the second direction Y. In FIG. 1, a rectangular block illustrates a layer where the pixel rows 120 are located, and a rectangular block illustrates a layer where the prism array 200 is located.

The prism array 200 is located on a side of the layer where the pixel rows 120 are located facing away from the substrate 110. The prism array 200 includes multiple aspheric cylindrical prisms 210 extending in the first direction X and arranged in the second direction Y. The orthographic projection of at least one pixel row 120 on the substrate 110 overlaps the orthographic projection of an aspheric cylindrical prism 210 on the substrate 110. The core optical surface of a conventional cylindrical prism is a cylindrical surface, which has a curvature only in one direction and no curvature in the other direction. The aspheric cylindrical prism 210 retains the unidirectional light regulation feature of the conventional cylindrical prism and has a curvature only in one direction (specifically, the second direction Y) and no curvature in the other direction (specifically, the first direction X). The core optical surface of the aspherical cylindrical prism 210 is an aspherical cylindrical surface. Different from the constant curvature of the cylindrical surface, the curvature of the aspherical cylindrical surface varies with position.

In the embodiment of the present disclosure, the aspheric cylindrical prism 210 is disposed above sub-pixels 130. The aspheric cylindrical prism 210 deflects the light emitted from the sub-pixels 130, thereby reducing the angular distribution range of the emitted light after passing through the aspheric cylindrical prism 210, and concentrating the emitted light in a certain angular range instead of emitting light in all directions. In this way, more light energy is concentrated within the angular range (for example, an angle near a pitch angle β), thereby improving the collimation of the emitted light, adapting to the angle range of a user viewing a screen, improving the light energy utilization rate of the screen, and improving the energy efficiency of the screen. The screen includes the display panel and may further include at least one optical element that deflects the light emitted from the display panel.

Referring to FIG. 2, multiple sub-pixels 130 arranged in the first direction X may constitute one pixel. Exemplarily, the sub-pixels 130 of the pixel include a first sub-pixel 131, a second sub-pixel 132, and a third sub-pixel 133. The first sub-pixel 131 emits red light, the second sub-pixel 132 emits green light, and the third sub-pixel 133 emits blue light. The light emitted from the first sub-pixel 131, the second sub-pixel 132, and the third sub-pixel 133 that are in the pixel is combined to produce a color to be displayed. Multiple sub-pixels 130 arranged in the second direction Y cannot visually combine their colors into a color emitted by a single pixel due to the excessively long distance between adjacent sub-pixels 130.

In one or more embodiments, referring to FIGS. 1 to 3, an orthographic projection of one pixel row 120 on the substrate 110 is located within the orthographic projection of the aspheric cylindrical prism 210 on the substrate 110. One aspherical cylindrical prism 210 covers one pixel row 120, thus helping dispose sub-pixels 130 in this pixel row 120 at appropriate positions. For example, a sub-pixel 130 is disposed correspondingly according to the focal point of the aspherical cylindrical prism 210, concentrating more light energy into a preset angular range (for example, the angular range where the angle near the pitch angle β is located) and improving the collimation of the emitted light. An orthographic projection on the substrate 110 refers to a projection in the third direction Z. The third direction Z is perpendicular to a plane where the substrate 110 is located. In an example, the first direction X, the second direction Y, and the third direction Z constitute a three-dimensional rectangular coordinate system.

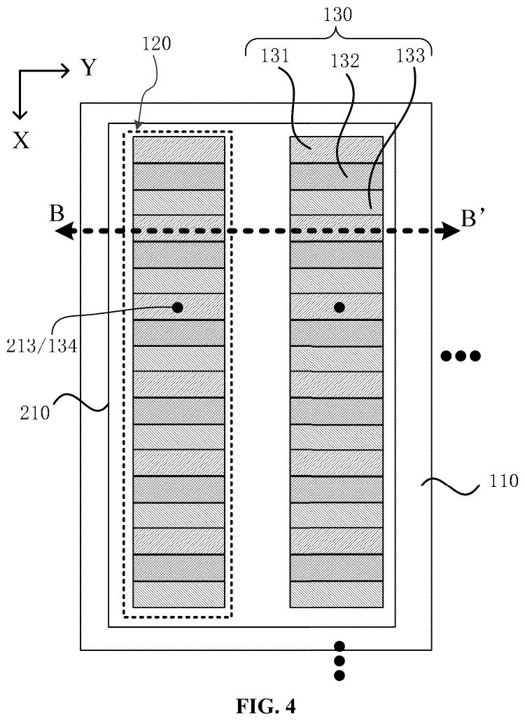

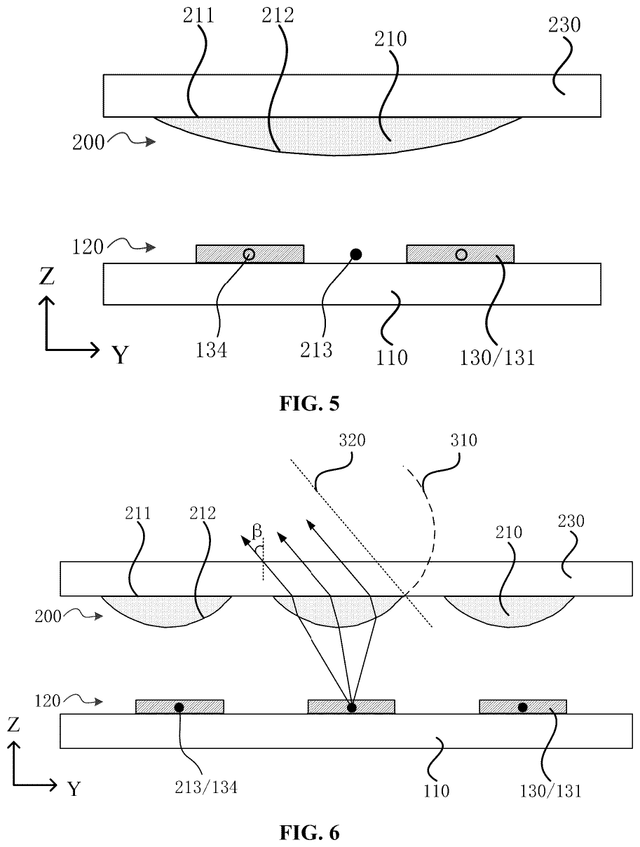

FIG. 4 is another top view of a display panel according to an embodiment of the present disclosure. FIG. 5 is a cross-sectional view taken along direction BB′ of FIG. 4. Referring to FIGS. 4 and 5, the orthographic projection of at least two pixel rows 120 on the substrate 110 is located within the orthographic projection of the aspheric cylindrical prism 210 on the substrate 110. One aspheric cylindrical prism 210 covers at least two pixel rows 120 (FIGS. 4 and 5 illustrate that one aspheric cylindrical prism 210 covers two pixel rows 120).

FIG. 6 is another cross-sectional view of a display panel according to an embodiment of the present disclosure. Referring to FIG. 6, the direction of light propagation is indicated by arrows in FIG. 6. The cross section of the aspheric cylindrical prism 210 is a part of an aspheric surface 310. The aspheric surface is symmetric about a first axis 320. The extension direction of the first axis 320 is parallel to the light emission direction of the central light in a light beam emitted from the display panel.

The aspheric surface 310 may include, for example, a paraboloid and an even-order aspheric surface. The aspheric cylindrical prism 210 deflects the light emitted from the sub-pixel 130 and then emits the light in the extension direction of the first axis 320 of the aspheric surface 310. The light deflected by the aspheric cylindrical prism 210 and then emitted outside the display panel is collimated light. The parallelism of the collimated light is relatively high and is close to parallel light. The angular distribution of the light beam in the collimated light is in a relatively small range. The central light in a light beam emitted from the display panel is the central light of the collimated light, and the rest of the light is symmetrical about the central light.

In one or more embodiments, referring to FIG. 6, the curvature of the cross section of the aspherical cylindrical surface 210 is not a constant value but varies with position. In the second direction, the curvature of the cross section of the aspheric cylindrical prism 210 gradually increases first and then gradually decreases. In the second direction Y, the curvature of the cross section of the aspherical cylindrical prism 210 is relatively great in the middle of the aspherical cylindrical prism 210 and relatively small on each side of the aspherical cylindrical prism 210. The cross section of the aspheric cylindrical prism 210 may have different curvatures on two sides.

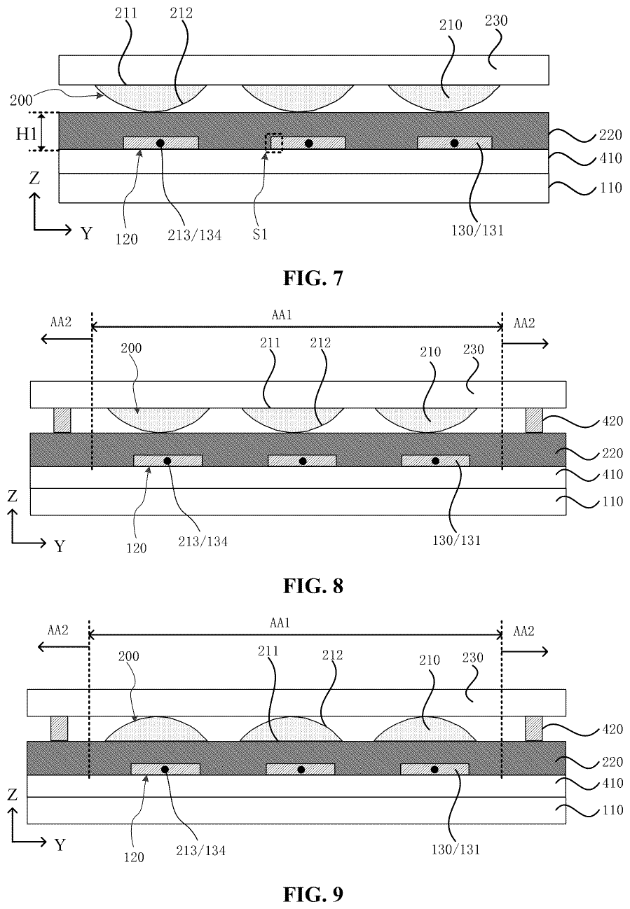

FIG. 7 is another cross-sectional view of a display panel according to an embodiment of the present disclosure. Referring to FIG. 7, the display panel further includes an organic film 220 located between the prism array 200 and the layer where the pixel rows 120 are located. The organic film 220 is in contact with the aspheric cylindrical prism 210. The organic film 220 provides a contact force for the aspheric cylindrical prism 210 and supports the aspheric cylindrical prism 210. In another aspect, the organic film 220 covers sub-pixels 130 in the pixel rows 120, protecting the sub-pixels 130, preventing the pressure of the aspherical cylindrical prism 210 from directly acting on the sub-pixels 130, and thus preventing the sub-pixels 130 from being damaged by excessive external force.

In one or more embodiments, referring to FIG. 7, when the thickness of the organic film 220 increases, the distance between the aspherical cylindrical prism 210 and the sub-pixels 130 increases; and when the thickness of the organic film 220 decreases, the distance between the aspherical cylindrical prism 210 and the sub-pixels 130 decreases. In the direction perpendicular to the plane where the substrate 110 is located, that is, in the third direction Z, the thickness of the organic film 220 is H1, and 15 μm≤H1≤50 μm. Accordingly, the distance between the aspheric cylindrical prism 210 and the sub-pixels 130 is set within a reasonable range. Even for the light emitted from an edge region (for example, a region S1) of a sub-pixel 130, after being deflected by the aspheric cylindrical prism 210, the angle of the emitted light does not deviate too far from a preset angle (for example, the pitch angle β), thereby improving the collimation of the emitted light.

FIG. 8 is another cross-sectional view of a display panel according to an embodiment of the present disclosure. Referring to FIG. 8, the display panel includes a first region AA1 and a second region AA2. The distance between the second region AA2 and an edge of the display panel is less than the distance between the first region AA1 and the edge of the display panel. The first region AA1 is located in a central region of the display panel. The second region AA2 is located in a peripheral region of the display panel. The second region AA2 is located in the periphery of the first region AA1. The pixel rows 120 are located in the first region AA1. The display panel further includes a cover plate 230 and a support member 420. The prism array 200 is disposed on a side of the cover plate 230 facing the substrate 110. The support member 420 is located in the second region AA2. The support member 420 is located between the cover plate 230 and the organic film 220. The support member 420 does not occupy the space of the first region AA1. Accordingly, the distance between the support member 420 in the second region AA2 and a sub-pixel 130 in the first region AA1 is relatively long, reducing adverse effects such as the pressure generated by the support member 420 on the sub-pixel 130 in the first region AA1. In another aspect, one end of the support member 420 is in contact with the cover plate 230, and the other end of the support member 420 is in contact with the organic film 220. The support member 420 provides a support force for the cover plate 230. A space for accommodating the prism array 200 is provided between the cover plate 230 and the organic film 220, thereby reducing the deformation of the aspherical cylindrical prism 210 in the prism array 200 due to pressure, for example, reducing the deformation at a contact point of the aspherical cylindrical prism 210 and the organic film 220.

Exemplarily, referring to FIG. 8, in the process of manufacturing the display panel, the prism array 200 may be formed on the cover plate 230. The pixel rows 120 and the organic film 220 may be formed on the substrate 110. Then, the cover plate 230 is turned over with the side on which the prism array 200 is disposed facing down and is abutted against a side of the substrate 110 on which the organic film 220 is disposed.

Exemplarily, referring to FIG. 8, the first region AA1 is a display region, and the second region AA2 is a non-display region. In other embodiments, each of the first region AA1 and the second region AA2 may be a display region.

Exemplarily, in some embodiments, no support member 420 may be provided, and the prism array 200 may be used as a support member to simplify the manufacturing process of the display panel and reduce the manufacturing cost.

In one or more embodiments, referring to FIG. 8, a surface of the aspheric cylindrical prism 210 includes a plane 211 and a curved surface 212. The plane 211 is connected to the curved surface 212. The curved surface 212 of the aspheric cylindrical prism 210 is a functional surface of the aspheric cylindrical prism 210 and is used for implementing light deflection. The curved surface 212 is located between the plane 211 and the layer where the pixel rows 120 are located. The curved surface 212 of the aspherical cylindrical prism 210 is disposed facing the pixel rows 120. Since the plane 211 of the aspherical cylindrical prism 210 is parallel to a plane where the cover plate 230 is located, and the plane 211 is closer to the cover plate 230 than the curved surface 212, in the process of manufacturing the display panel, the aspherical cylindrical prism 210 in the prism array 200 is able to be formed on the cover plate 230 through a process such as imprinting or etching, thereby simplifying the manufacturing process.

Exemplarily, a vertex of the curved surface 212 of the aspheric cylindrical prism 210 is in contact with the organic film 220. The curved surface 212 of the aspheric cylindrical prism 210 may also be contacted with air. Media on two sides of the curved surface 212 are a material forming the aspheric cylindrical prism 210 and air, respectively. The refractive index of the air is very small, thereby reducing the requirements of the refractive index of the material forming the aspheric cylindrical prism 210.

FIG. 9 is another cross-sectional view of a display panel according to an embodiment of the present disclosure. Referring to FIG. 9, the plane 211 is located between the curved surface 212 and the layer where the pixel rows 120 are located. The curved surface 212 of the aspherical cylindrical prism 210 is disposed facing the cover plate 230. The plane 211 is closer to the substrate 110 than the curved surface 212. In the process of manufacturing the display panel, the aspherical cylindrical prism 210 in the prism array 200 may be formed on a side of the organic film 220 facing away from the substrate through a process such as etching.

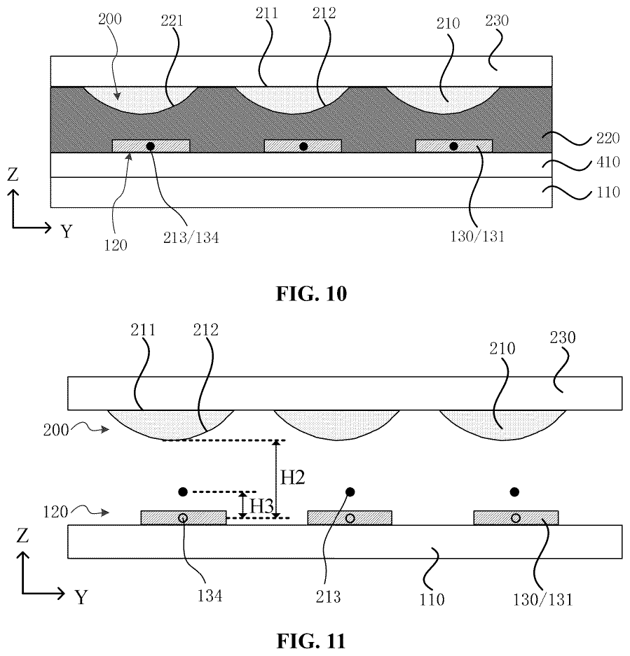

FIG. 10 is another cross-sectional view of a display panel according to an embodiment of the present disclosure. Referring to FIG. 10, a side of the organic film 220 facing the prism array 200 is provided with multiple grooves 221. The aspheric cylindrical prism 210 is located in a groove 221. The aspheric cylindrical prisms 210 may be located in the grooves 221 in a one-to-one manner. That is, a groove 221 accommodates an aspheric cylindrical prism 210. The refractive index of the aspheric cylindrical prism 210 is greater than the refractive index of the organic film 220. A large part of the curved surface 212 of the aspherical cylindrical prism 210 is in contact with the groove 221, increasing the contact area between the aspherical cylindrical prism 210 and the organic film 220, reducing the pressure per unit area, and thus reducing the deformation of the aspherical cylindrical prism 210 due to pressure.

In one or more embodiments, referring to FIGS. 2 and 3, the orthographic projection of the focal point 213 of the aspheric cylindrical prism 210 on the substrate 110 is located within the orthographic projection of a sub-pixel 130 on the substrate 110. The focal point 213 of the aspheric cylindrical prism 210 is disposed in the vicinity of the sub-pixel 130 so that the light emitted from the sub-pixel 130, after being deflected by the aspheric cylindrical prism 210, can be emitted as collimated light, improving the collimation of the emitted light.

Further, referring to FIGS. 2 and 3, the focal point 213 of the aspheric cylindrical prism 210 coincides with the center 134 of the sub-pixel 130. It may be understood that even if the focal point 213 of the aspherical cylindrical prism 210 coincides with the center 134 of the sub-pixel 130, the light emitted from a region outside the center 134 of the sub-pixel 130 (for example, the region S1 in FIG. 7) has a certain angle relative to the light emission direction of the central light in a light beam emitted from the display panel. The focal point 213 of the aspherical cylindrical prism 210 coincides with the center 134 of the sub-pixel 130, reducing the angular distribution range of the emitted light after passing through the aspheric cylindrical prism 210 and improving the collimation of the emitted light.

In other embodiments, the focal point 213 of the aspherical cylindrical prism 210 may not coincide with the center 134 of the sub-pixel 130.

FIG. 11 is another cross-sectional view of a display panel according to an embodiment of the present disclosure. Referring to FIG. 11, a surface of the aspheric cylindrical prism 210 includes a plane 211 and a curved surface 212. The plane 211 is connected to the curved surface 212. In the direction perpendicular to the plane where the substrate 110 is located, that is, in the third direction Z, the distance between a vertex of the curved surface 212 and the center 134 of the sub-pixel 130 is H2. In the example shown in FIG. 11, the curved surface 212 is located between the plane 211 and the layer where the pixel rows 120 are located. In the third direction Z, the minimum distance between the curved surface 212 and the center 134 of the sub-pixel 130 is H2. The distance between the focal point 213 of the aspherical cylindrical prism 210 and the center 134 of the sub-pixel 130 is H3.

$$\frac{H 3}{H 2} < 0.3 .$$

In the embodiment of the present disclosure, a certain distance is allowed to exist between the center 134 of the sub-pixel 130 and the focal point 213 of the aspheric cylindrical prism 210. That is, defocus within a certain distance range is allowed. This certain range of defocus provides better adaptability for users of different heights. Users of different heights have different eye heights in the vertical direction, requiring a certain angular range of the emission angle of the display panel. Accordingly, the sub-pixel 130 may be set to have a certain degree of defocus. In one or more embodiments, referring to FIG. 11, the focal point 213 of the aspheric cylindrical prism 210 is located between the layer where the pixel rows 120 are located and the layer where the prism array 200 is located. When the focal point 213 of the aspheric cylindrical prism 210 is located above the layer where the pixel rows 120 are located, the luminous flux is increased, thereby improving the light utilization rate of the display panel and the luminous brightness of the display panel.

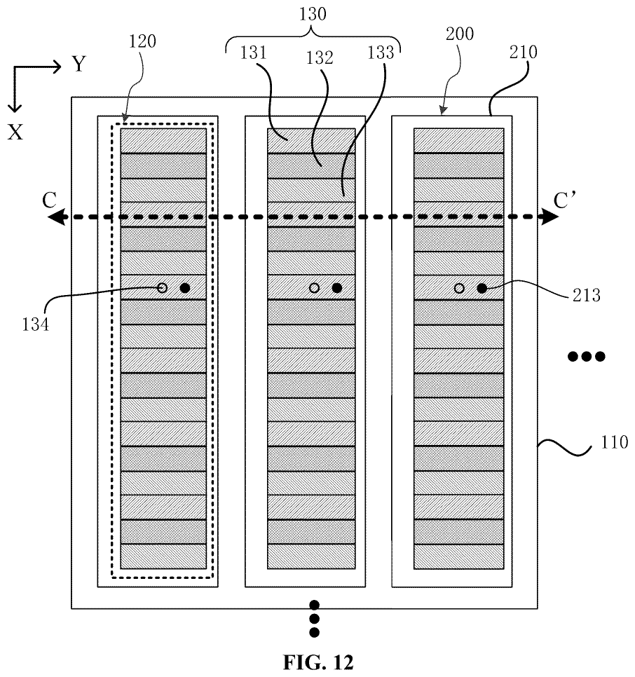

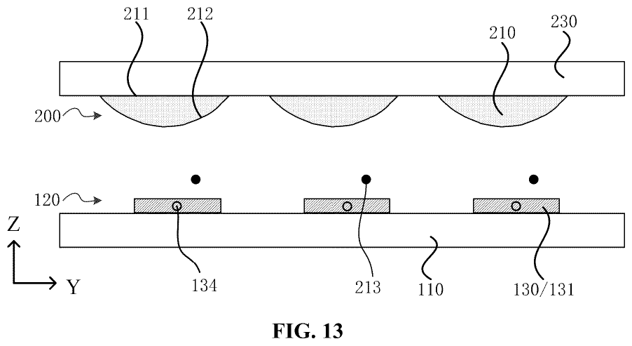

FIG. 12 is another top view of a display panel according to an embodiment of the present disclosure. FIG. 13 is a cross-sectional view taken along direction CC′ of FIG. 12. Referring to FIGS. 12 and 13, the orthographic projection of the focal point 213 of the aspheric cylindrical prism 210 on the substrate 110 and the orthographic projection of the center 134 of the sub-pixel 130 on the substrate 110 are spaced apart. A certain distance exists between the orthographic projection of the focal point 213 of the aspheric cylindrical prism 210 on the substrate 110 and the orthographic projection of the center 134 of the sub-pixel 130 on the substrate 110. In the embodiment of the present disclosure, there is not only upper and lower defocus but also left and right defocus.

Exemplarily, referring to FIG. 11, adjacent aspherical cylindrical prisms 210 are spaced apart. For example, in some scenarios, due to process limitations, the entire layout space cannot be filled with the aspheric cylindrical prisms 210, and a gap exists between adjacent aspheric cylindrical prisms 210.

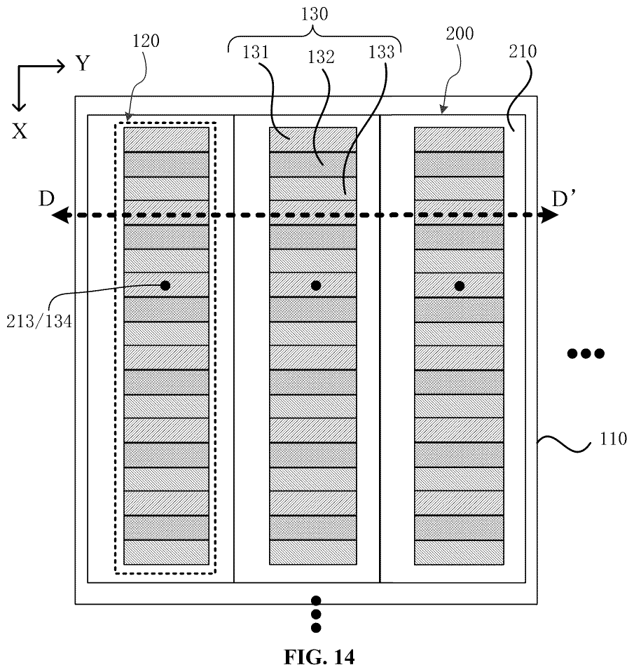

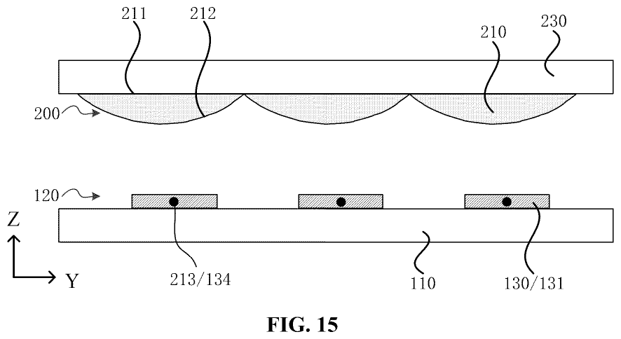

FIG. 14 is another top view of a display panel according to an embodiment of the present disclosure. FIG. 15 is a cross-sectional view taken along direction DD′ of FIG. 14. Referring to FIGS. 14 and 15, adjacent aspheric cylindrical prisms 210 are in contact with each other. No gap exists between adjacent aspheric cylindrical prisms 210. Accordingly, at least in the first region AA1, the aspherical cylindrical prism 210 fills the entire layout space. Compared with a gap with no optical effect, the aspheric cylindrical prism 210 has an optical effect and is able to deflect the light incident thereon, thereby improving the light utilization rate of the display panel and the luminous brightness of the display panel.

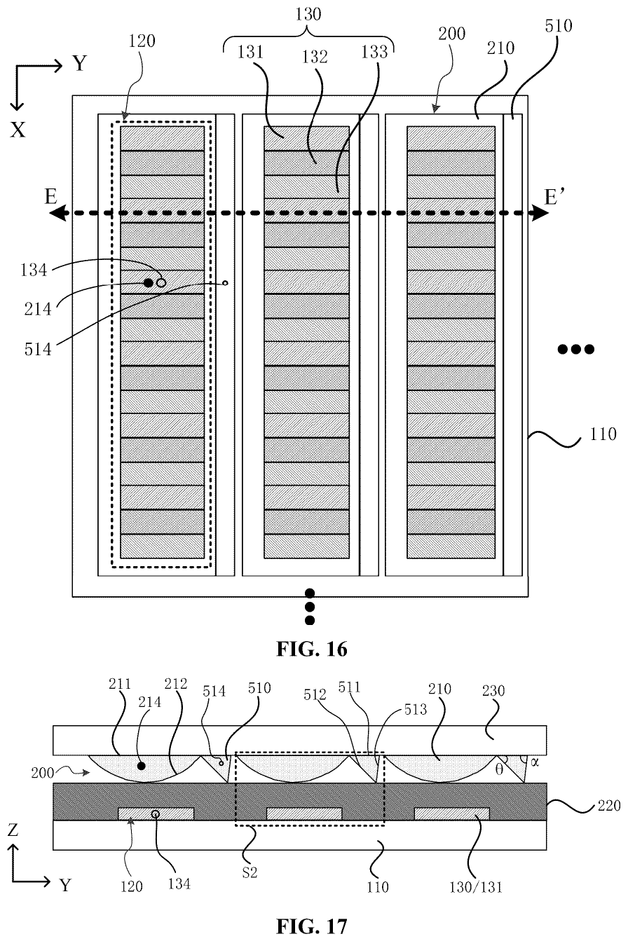

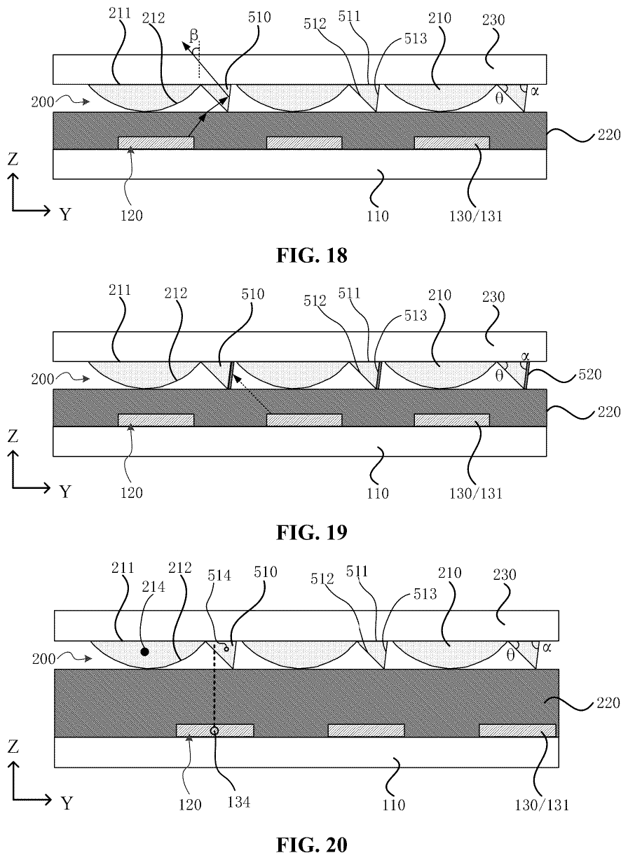

FIG. 16 is another top view of a display panel according to an embodiment of the present disclosure. FIG. 17 is a cross-sectional view taken along direction EE′ of FIG. 16. FIG. 18 is another cross-sectional view of a display panel according to an embodiment of the present disclosure. The transmission direction of light is indicated by arrows in FIG. 18. Referring to FIGS. 16 to 18, the display panel further includes a triangular prism 510 extending in the first direction X and located between adjacent aspheric cylindrical prisms 210 in the second direction Y. In the embodiment of the present disclosure, the triangular prism 510 is used for filling a gap with no optical effect. The large-angle light emitted from the sub-pixel 130 is deflected by the triangular prism 510 and then emitted according to the preset angular range (for example, the angular range where the angle near the pitch angle β is located), thereby recovering the large-angle emitted light and increasing the light emission brightness of the display panel.

Exemplarily, multiple triangular prisms 510 are arranged in the second direction Y. In the second direction Y, the aspheric cylindrical prisms 210 and the triangular prisms 510 are spaced apart and alternately arranged.

In one or more embodiments, referring to FIGS. 16 to 18, in the second direction Y, the orthographic projection of the center 134 of the sub-pixel 130 on the substrate is located between the orthographic projection of the center 214 of the aspheric cylindrical prism 210 on the substrate 110 and the orthographic projection of the center 514 of the triangular prism 510 on the substrate 110. Therefore, the aspheric cylindrical prism 210 may emit most of the light emitted from the sub-pixel 130 according to the preset angle range. The triangular prism 510 may emit the large-angle light among the light emitted from the sub-pixel 130 according to the preset angle range.

Exemplarily, regardless of the height of the center 134 of the sub-pixel 130 in the third direction Z, the height of the center 214 of the aspherical cylindrical prism 210 in the third direction Z, and the height of the center 514 of the triangular prism 510 in the third direction Z, the center 214 of the aspherical cylindrical prism 210 and the center 514 of the triangular prism 510 are located on two sides of the center 134 of the sub-pixel 130 in the region S2 shown in FIG. 17. The region S2 may be regarded as a basic repetition unit in the second direction Y.

In one or more embodiments, referring to FIGS. 16 to 18, the triangular prism 510 includes a first surface 511, a second surface 512, and a third surface 513. In the second direction Y, the first surface 511 is parallel to the plane where the substrate 110 is located. The plane where the substrate 110 is located is an XY plane determined by the first direction X and the second direction Y. In the second direction Y, the second surface 512 is located between the aspheric cylindrical prism 210 and the third surface 513. The first surface 511 and the second surface 512 form a first included angle θ. The first surface 511 and the third surface 513 form a second included angle α. The first included angle θ is less than the second included angle α. The second included angle α is less than 90°. Accordingly, the large-angle light emitted from the sub-pixel 130 may enter the triangular prism 510 from the second surface 512 and be reflected on the third surface 513. The reflected light is emitted outside the triangular prism 510 through the first surface 511 and finally emitted according to the preset angle range.

Further, referring to FIGS. 16 to 18, the first included angle is denoted by θ. The second included angle is denoted by α. α>θ+41.8°. The refractive index of the material forming the triangular prism 510 is greater than the refractive index of air. In the case where α>θ+41.8°, total reflection occurs on the third surface 513, improving the reflectivity of the light on the third surface 513, improving the light utilization rate of the display panel, and improving the luminous brightness of the display panel.

FIG. 19 is another cross-sectional view of a display panel according to an embodiment of the present disclosure. Referring to FIG. 19, the display panel further includes a reflective metal layer 520 disposed on the third surface 513. In the second direction Y, the reflective metal layer 520 is located on a side of the triangular prism 510 facing away from the aspheric cylindrical prism 210. In the case where the reflective metal layer 520 is provided, total reflection on the third surface 513 may not be required, and reflectivity may be relatively high, thus reducing the design requirements of the triangular prism 510 and increasing the stability of the triangular prism 510. Even if the triangular prism 510 is deformed by an external force in the process of manufacturing and using the display panel, the reflection angle of the light at the position of the reflective metal layer 520 is basically not affected, and the angle of the light finally emitted outside the display panel is not affected. In another aspect, the reflective metal layer 520 may also block the crosstalk light in adjacent repetition units (as shown by dashed arrows in FIG. 19).

In one or more embodiments, referring to FIGS. 16 and 17, in the direction perpendicular to the plane where the substrate 110 is located, that is, in the third direction Z, the center 134 of the sub-pixel 130 overlaps the aspheric cylindrical prism 210. This arrangement enables the aspheric cylindrical prism 210 to deflect most of the light emitted from the sub-pixel 130 and enables the triangular prism 510 to deflect a small part of the light emitted from the sub-pixel 130. In an example, the triangular prism 510 deflects the large-angle light among the light emitted from the sub-pixel 130.

It needs to be noted that the position of the center 134 of the sub-pixel 130 is related to the thickness of the organic film 220. In the case where the emission angle is selected, the thicker the organic film 220 is, the closer the position of the center 134 of the sub-pixel 130 is to the center 514 of the triangular prism 510; the thinner the organic film 220 is, the closer the position of the center 134 of the sub-pixel 130 is to the center 214 of the aspherical cylindrical prism 210.

FIG. 20 is another cross-sectional view of a display panel according to an embodiment of the present disclosure. Referring to FIG. 20, the organic film 220 is relatively thick. In the third direction Z, the center 134 of the sub-pixel 130 overlaps the triangular prism 510.

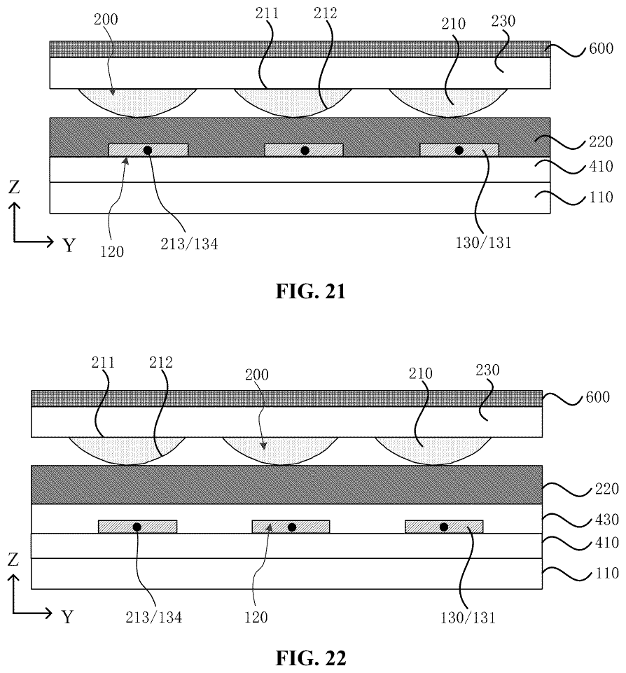

FIG. 21 is another cross-sectional view of a display panel according to an embodiment of the present disclosure. Referring to FIG. 21, the display panel further includes a collimation film 600 used for filtering out the crosstalk light outside the preset angle range, improving the collimation of the emitted light. The position of the collimation film 600 may be set according to needs.

Exemplarily, referring to FIG. 21, the sub-pixel 130 includes a micro light-emitting diode (micro-LED) or a mini-LED. The micro-LED or mini-LED includes an inorganic light-emitting diode. The inorganic light-emitting diode has a relatively small occupation area and higher luminance brightness, thus enabling a higher pixel density to be set.

FIG. 22 is another cross-sectional view of a display panel according to an embodiment of the present disclosure. Referring to FIG. 22, the sub-pixel 130 includes an organic light-emitting diode. The organic light-emitting diode includes an anode, an auxiliary functional layer (such as a hole transport layer, an electron transport layer, or an electron injection layer), a light-emitting layer, and a cathode. When a voltage is applied to the anode and the cathode, holes and electrons are transported and moved to the light-emitting layer separately and are recombined in the light-emitting layer to form excitons. Excitons migrate under the action of an electric field, transfer energy to the luminescent material, and excite electrons in the luminescent material to transition from the ground state to the excited state. Through radiative deactivation, the excited state energy generates photons and releases light energy.

Exemplarily, referring to FIG. 22, the display panel may further include a thin-film encapsulation layer 430 that covers the sub-pixels 130 and prevents water vapor and oxygen from eroding the sub-pixels 130, thus improving the service life of the display panel. The thin-film encapsulation layer 430 is located between the organic film 220 and the layer where the pixel rows 120 are located.

In other embodiments, the display panel may also be a liquid crystal display panel. In the liquid crystal display panel, the size of a sub-pixel may be defined by the opening of a black matrix. The sub-pixel includes a pixel electrode, a common electrode, and liquid crystal molecules within a range defined by the opening of the black matrix.

Exemplarily, referring to FIGS. 21 and 22, the display panel may further include a pixel circuit 410. A layer where the pixel circuit 410 is located is located between the substrate 110 and the layer where the pixel rows 120 are located. The pixel circuit 410 is used for providing a drive voltage or a drive current to the sub-pixels 130 in the pixel rows 120.

In one or more embodiments, referring to FIG. 18, the triangular prism 510 and the aspheric cylindrical prism 210 are made of the same material. Accordingly, the triangular prism 510 and the aspheric cylindrical prism 210 may be formed in the same process, thereby simplifying the process.

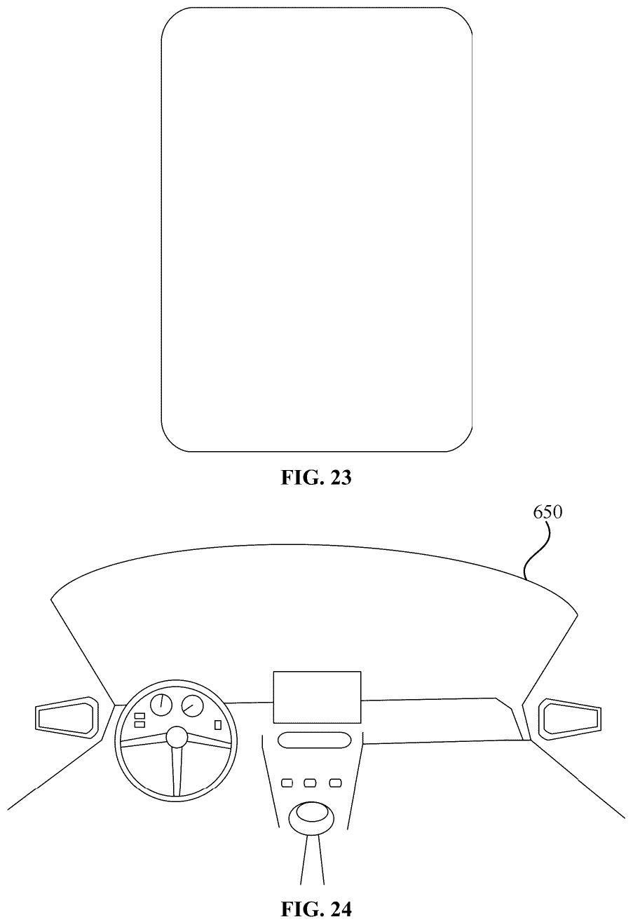

FIG. 23 is a view of a display device according to an embodiment of the present disclosure. Referring to FIG. 23, the display device includes the display panel in the preceding embodiments. The display device provided in the embodiment of the present disclosure may be a vehicle-mounted display shown in FIG. 23 or may be any electronic product with a display function, including, but not limited to: a television, a laptop, a desktop display, an electronic paper display device, a tablet computer, a digital camera, a smart bracelet, smart glasses, industry-controlling equipment, a medical display screen, and a touch interactive terminal, which is not specifically limited in this embodiment of the present disclosure.

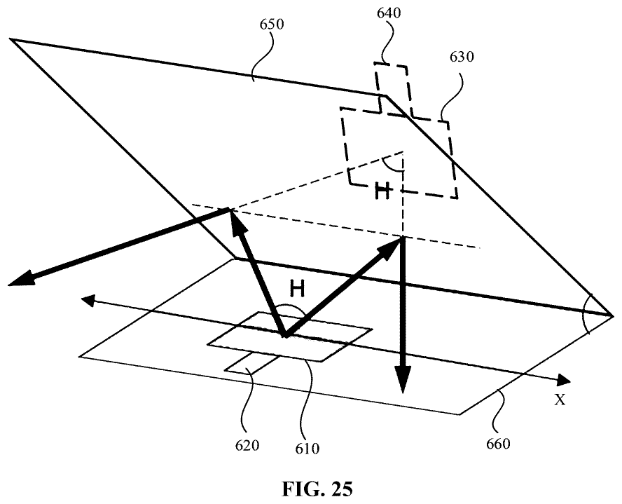

FIG. 24 is a diagram of a carrier according to an embodiment of the present disclosure. FIG. 25 is a diagram of another carrier according to an embodiment of the present disclosure. Referring to FIGS. 24 and 25, the carrier includes a display device 610 and a windscreen 650.

The light emitted from the display device 610 is transmitted to the windscreen 650. The windscreen 650 may reflect the light into an eye box and form a virtual image on the other side of the windscreen 650 so that a driver can clearly see the key information of a vehicle and know key information such as the running state of the vehicle, navigation guidance, and safety warning in time without taking his sight off the road, thereby making a corresponding driving decision and operation.

A head-up display provided in this embodiment of the present disclosure may be a vehicle-mounted head-up display or any other product with a head-up display function, including but not limited to: a glass head-up display, a mobile phone head-up display, a home head-up display, an airplane head-up display, and a workshop head-up display, which is not specifically limited in the embodiment of the present disclosure. The carrier may be, for example, an automobile, an airplane, or a ship.

Exemplarily, the display device 610 has a relatively large light emission angle in the direction of an azimuth angle H. The feature of high collimation is presented in the direction of the pitch angle β. In the embodiment of the present disclosure, the central angle of the emitted light beam is set at a certain angle to the vertical direction. The light is emitted at an angle near the pitch angle β and projected onto the windscreen 650. The first direction X is the horizontal direction and is parallel to the connection direction of a user's eyes.

Exemplarily, the display device 610 is disposed on a platform 660 inside the carrier. The display device 610 is electrically connected to a control structure inside the carrier through a connection line 620. A first virtual image 630 is formed on a side of the display device 610 facing the windscreen 650. In order to illustrate the way in which the display device 610 forms an image on the windscreen 650, the position of a second virtual image 640 corresponding to the connection line 620 is also illustrated in FIG. 25. It may be understood that the second virtual image 640 is not visible to the user's eye in an actual product because the connection line 620 does not emit light.

It is to be noted that the preceding are preferred embodiments of the present disclosure and technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising:
a substrate;
a plurality of pixel rows located on a side of the substrate, extending in a first direction, and arranged in a second direction, wherein a pixel row of the plurality of pixel rows comprises a plurality of sub-pixels arranged in the first direction, and the first direction intersects the second direction; and
a prism array located on a side of a layer where the plurality of pixel rows are located facing away from the substrate, the prism array comprises a plurality of aspheric cylindrical prisms extending in the first direction and arranged in the second direction;
wherein an orthographic projection of at least one of the plurality of pixel rows on the substrate overlaps an orthographic projection of an aspheric cylindrical prism of the plurality of aspheric cylindrical prisms on the substrate.

2. The display panel according to claim 1, wherein an orthographic projection of one of the plurality of pixel rows on the substrate is located within the orthographic projection of the aspheric cylindrical prism on the substrate.

3. The display panel according to claim 1, wherein a cross section of the aspheric cylindrical prism is a part of an aspheric surface, and the aspheric surface is symmetric about a first axis; and
an extension direction of the first axis is parallel to a light emission direction of central light in a light beam emitted from the display panel.

4. The display panel according to claim 3, wherein in the second direction, a curvature of the cross section of the aspheric cylindrical prism gradually increases first and then gradually decreases.

5. The display panel according to claim 1, further comprising an organic film located between the prism array and the layer where the plurality of pixel rows are located, wherein the organic film is in contact with the aspheric cylindrical prism.

6. The display panel according to claim 5, comprising a first region and a second region, wherein a distance between the second region and an edge of the display panel is less than a distance between the first region and the edge of the display panel, and the plurality of pixel rows are located in the first region; and
a cover plate and a support member, wherein the prism array is disposed on a side of the cover plate facing the substrate, the support member is located in the second region, and the support member is located between the cover plate and the organic film.

7. The display panel according to claim 1, wherein a surface of the aspheric cylindrical prism comprises a plane and a curved surface, and the plane is connected to the curved surface; and
the curved surface is located between the plane and the layer where the plurality of pixel rows are located.

8. The display panel according to claim 5, wherein a side of the organic film facing the prism array is provided with a plurality of grooves, and the aspheric cylindrical prism is located in one of the plurality of grooves; and
a refractive index of the aspheric cylindrical prism is greater than a refractive index of the organic film.

9. The display panel according to claim 1, wherein an orthographic projection of a focal point of the aspheric cylindrical prism on the substrate is located within an orthographic projection of a sub-pixel of the plurality of sub-pixels on the substrate.

10. The display panel according to claim 9, wherein a surface of the aspheric cylindrical prism comprises a plane and a curved surface, and the plane is connected to the curved surface; and
in a direction perpendicular to a plane where the substrate is located, a distance between a vertex of the curved surface and a center of the sub-pixel is H2, and a distance between the focal point and the center of the sub-pixel is H3, wherein
$$\frac{H 3}{H 2} < 0.3 .$$

11. The display panel according to claim 10, wherein the focal point is located between the layer where the plurality of pixel rows are located and a layer where the prism array is located.

12. The display panel according to claim 1, wherein adjacent aspheric cylindrical prisms of the plurality of aspheric cylindrical prisms are in contact with each other.

13. The display panel according to claim 1, further comprising a triangular prism extending in the first direction and located between adjacent aspheric cylindrical prisms of the plurality of aspheric cylindrical prisms in the second direction.

14. The display panel according to claim 13, wherein in the second direction, an orthographic projection of a center of a sub-pixel of the plurality of sub-pixels on the substrate is located between an orthographic projection of a center of the aspheric cylindrical prism on the substrate and an orthographic projection of a center of the triangular prism on the substrate.

15. The display panel according to claim 14, wherein the triangular prism comprises a first surface, a second surface, and a third surface; and in the second direction, the first surface is parallel to a plane where the substrate is located, and the second surface is located between the aspheric cylindrical prism and the third surface; and
the first surface and the second surface form a first included angle, the first surface and the third surface form a second included angle, the first included angle is less than the second included angle, and the second included angle is less than 90°.

16. The display panel according to claim 15, wherein the first included angle is denoted by θ, the second included angle is denoted by α, and α>θ+41.8°.

17. The display panel according to claim 15, further comprising a reflective metal layer disposed on the third surface.

18. The display panel according to claim 14, wherein in a direction perpendicular to a plane where the substrate is located, a center of the sub-pixel overlaps the aspheric cylindrical prism.

19. A display device, comprising a display panel, wherein the display panel comprises:
a substrate;
a plurality of pixel rows located on a side of the substrate, extending in a first direction, and arranged in a second direction, wherein a pixel row of the plurality of pixel rows comprises a plurality of sub-pixels arranged in the first direction, and the first direction intersects the second direction; and
a prism array located on a side of a layer where the plurality of pixel rows are located facing away from the substrate, the prism array comprises a plurality of aspheric cylindrical prisms extending in the first direction and arranged in the second direction;
wherein an orthographic projection of at least one of the plurality of pixel rows on the substrate overlaps an orthographic projection of an aspheric cylindrical prism of the plurality of aspheric cylindrical prisms on the substrate.

20. A carrier, comprising a display device and a windscreen, wherein the display panel comprises:
a substrate;
a plurality of pixel rows located on a side of the substrate, extending in a first direction, and arranged in a second direction, wherein a pixel row of the plurality of pixel rows comprises a plurality of sub-pixels arranged in the first direction, and the first direction intersects the second direction; and
a prism array located on a side of a layer where the plurality of pixel rows are located facing away from the substrate, the prism array comprises a plurality of aspheric cylindrical prisms extending in the first direction and arranged in the second direction;
wherein an orthographic projection of at least one of the plurality of pixel rows on the substrate overlaps an orthographic projection of an aspheric cylindrical prism of the plurality of aspheric cylindrical prisms on the substrate.
